(19) United States
(12) Patent Application Publication
(10) Pub. No.: US 2004/0251897 A1
(43) Pub. Date: Dec. 16, 2004

(54) Fluxgate magnetometer with rotating core

(75) Inventor: Erik Horsdal Pedersen, Arhus V (DK)

Correspondence Address: NIXON PEABODY, LLP, 401 9TH STREET, NW, SUITE 900, WASHINGTON, DC, 20004-2128, US

(73) Assignee: DanMag ApS, Arhus (DK)

(21) Appl. No.: 10/461,421

(22) Filed: Jun. 16, 2003

(51) Int. Cl. G01R 33/04; G01R 35/00

(52) U.S. Cl. 324/253; 324/202

(57) ABSTRACT

A magnetometer for measuring a magnetic field, comprising a fluxgate sensor with at least one ferromagnetic core, a primary, electrically conducting coil arranged around the core for periodical magnetisation of the core into magnetic saturation by an alternating electric current through the primary coil, and a secondary, electrically conducting coil arranged around the at least one ferromagnetic core for producing a measurable electromotive force as a response signal, wherein the magnetometer has means for rotating the at least one core of the fluxgate sensor with a steady rotation inside the coils during the measurement of the magnetic field.

### FIELD OF THE INVENTION

The present invention relates to fluxgate magnetometers and calibration method for fluxgates with rotating cores.

### BACKGROUND OF THE INVENTION

Fluxgate sensors are used for detecting and measuring magnetic fields. The fluxgate principle is explained in a review article by F.Primdahl published by The Institute of Physics in Journal of Physics E, Vol. 12, p. 241-253 (1979).

It may be recognized that a fluxgate sensor is similar to a transformer. In the simplest form, it consists of primary and secondary coils wound on a straight, ferromagnetic core as illustrated in FIG. 1. The core 3 is magnetized by a periodic current I in the primary coil 1 and an electromagnetic force E is induced in the secondary coil 2.

The magnetization of the core influences the magnetic field B in dependency of the permeability of the material. For a ferromagnetic material, hysteresis is experienced between B and H as sketched in FIG. 2e.

When the electromotive force induced in the secondary windings is plotted against time or the current in the primary coil, it traces out the derivative of the magnetization curve for the core material. This is known as the gating curve as described in the above mentioned article by Primdahl. Gating curves are illustrated in FIG. 2d and 3d.

Due to the hysteresis of the core material, see FIG. 2e , the gating curve in FIG. 2d shows two different branches. The positive branch corresponds to increasing current (dI/dt>0) and the negative one to decreasing current (dI/dt<0). The two branches form a symmetric image as illustrated in FIG. 2d, if the current does not have a DC offset (I_{DC}=0) and no external magnetic field is present. The image becomes asymmetric with respect to I=0, as illustrated in FIG. 3d, if an external magnetic field with a component parallel to the ferromagnetic core (B_{z}≠0) is present, for example due to Earth's magnetic field. However, the symmetry can be restored quite accurately by for example a DC offset I_{DC}≠0, which then is a sensitive measure of B_{z}, B_{z}=B_{z}(I_{DC}). This offset current I_{DC}≠0 is automatically adjusted in fluxgate sensors for measuring the strength of the magnetic field. We use this method to illustrate the operation of a fluxgate sensor, but the symmetry can be restored also by a DC current in a separate compensation coil or in the secondary coil.

A variety of Fluxgate sensors have been developed, and various methods of detecting the asymmetry exist, but all known systems need calibration against an absolute magnetometer if absolute measurements are desired. Fluxgate magnetometers typically cover magnetic field strengths of between less than 10⁻³ Tesla and a value substantially less than the Earth's magnetic strength of about 10⁻⁴ Tesla. However, absolute magnetometry is difficult and expensive at such field strengths.

It is therefore the purpose of the invention to provide a novel fluxgate sensor with an improved calibration method.

### DESCRIPTION/SUMMARY OF THE INVENTION

This purpose is achieved by a flux gate magnetometer for measuring a magnetic field, comprising a fluxgate sensor with

at least one ferromagnetic core,

a primary, electrically conducting coil arranged around the core for periodical magnetisation of the core into magnetic saturation by an alternating electric current through the primary coil, and

a secondary, electrically conducting coil arranged around the at least one ferromagnetic core for producing a measurable electromotive force as a response signal, wherein the magnetometer has means for rotating the at least one core of the fluxgate sensor with a steady rotation inside the coils during the measurement of the magnetic field.

Due to the rotating core, the magnetometer according to the invention is capable of self-calibration. The present invention utilizes the gyromagnetic effect to realize such a self-calibrating fluxgate magnetometer suitable for the absolute measurement and continuous monitoring of the Earths magnetic field or other magnetic fields of the same or differing order of magnitude.

The gyromagnetic effect will be explained in the following. Due to the intrinsic spin, an electron has both an angular momentum and a magnetic moment, which are proportional. If the core material is rotated, the mechanical angular momenta of the electrons will tend to align themselves along the rotation axis. This implies alignment also of the magnetic moments, so the material is magnetized by the rotation. This is the so-called magnetomechanical or gyromagnetic effect described for example by the American Physical Society in Reviews of Modem Physics, Vol. 7, p. 129-166 (1935). The magnetization is exactly equal to the magnetization that would be achieved by an external magnetic field which is anti-parallel to the rotation axis and has the strength B=Ω, where Ω is the angular rotation frequency and the variables are measured in atomic units.

The magnetomechanical effect ties the strength of a magnetic field to a frequency. The magnetic field may thus be measured in frequency units. The conversion factor is the gyromagnetic ratio of the electron which is a well-known constant-of-nature. In SI-units, the magnetic field-strength is given by the Larmor relation 2πf=gₑe/(2m)B, where f is the frequency of rotation, gₑ=−2.0023093043737 the g-factor of the electron, and e/m=−1.758820174×10¹¹ C/kg its charge-to-mass ratio. The numerical value of the conversion factor is 35.6825 nT/kHz. The Earths magnetic field varies from place to place and as a function of time, but near the Earths surface it is normally within the interval 30,000-100,000nT.

In a practical embodiment, the magnetometer has means for measuring the electromotive force produced in the secondary coil.

In a further embodiment, the magnetometer has means for supplying an alternating electric current through the primary coil.

Optionally, the fluxgate sensor has two cores, each core being surrounded by a primary coil, both cores being surrounded by one secondary coil, the two cores being configured to be rotated in the same direction by rotation means.

The magnetometer according to the invention allows a calibration method which is improved relative to prior art.

A local calibration, which is explained in more detail below, of a magnetometer according to the invention is given by the following. The magnetometer has a fluxgate sensor with

at least one ferromagnetic core,

a primary, electrically conducting coil arranged around the core for periodical magnetisation of the core into magnetic saturation by an alternating electric current through the primary coil, and

a secondary, electrically conducting coil arranged around the at least one ferromagnetic core for producing a measurable electromotive force as a response signal,

wherein the magnetometer has means for rotating the at least one core of the fluxgate sensor with a steady rotation inside the coils during the selected measurements of the magnetic field,

the fluxgate sensor is configured to provide and adjust a DC offset current I_{DC} in the primary coil, the value of the DC offset current in the primary coil being adjusted to create a magnetic field balancing the magnetic field B experienced by the secondary coil,

the method comprising,

for an external magnetic field B_{E} in the direction parallel with the core, without rotation of the core at rotation frequency Ω,

measuring the DC offset current I_{DC}(Ω=0) in the primary coil,

bringing the core into a steady state of rotation at frequency Ω, Ω≠0,

measuring the rotation frequency Ω,

measuring the DC offset current I_{DC}(Ω) at the rotation frequency Ω,

using the gyromagnetic effect for determination of the gradient ΔB/ΔΔI_{DC} of the external magnetic field variation ΔB relative to the variation in the offset current ΔIDC necessary to balance this variation, this determination implying calculating the ratio Ω/(I_{DC}(Ω)−I_{DC}(0)) between the rotation frequency 106 and the difference between the offset current I_{DC}(Ω) at frequency Ω and the offset current I_{DC}(0) without rotation of the core.

The external magnetic field B_{E} has to be understood as the field which is present when the magnetometer is not magnetically shielded. Usually, a background magnetic field from Earth is present. However, in the case that the magnetometer is used in a region which is magnetically field free, for example when placed in a Li-metal shielded region, B_{E} is simply zero.

For a zero point calibration, the method comprises

providing a volume without a magnetic field component in a first direction,

placing the fluxgate sensor in this volume with the core aligned parallel with this first direction,

measuring the DC offset current in the primary coil I_{DC0} in this volume for calibration of the magnetometer at zero magnetic field strength.

An extended calibration for a large range can be performed in the following way, also explained in more detail in the detailed description. In this case, the magnetometer has a fluxgate sensor with

at least one ferromagnetic core,

a primary, electrically conducting coil arranged around the core for periodical magnetisation of the core into magnetic saturation by an alternating electric current through the primary coil, and

a secondary, electrically conducting coil arranged around the at least one ferromagnetic core for producing a measurable electromotive force as a response signal,

wherein the magnetometer has means for rotating the at least one core of the fluxgate sensor with a steady rotation inside the coils during the measurement of the magnetic field,

the fluxgate sensor being configured to provide and adjust a DC offset current I_{DC} in the primary coil, the value of the DC offset current in the primary coil being adjusted to create a magnetic field balancing the magnetic field B experienced by the secondary coil,

where the magnetometer may be calibrated by a method for calibration comprising

for an external magnetic field B_{E}, without rotation of the core at rotation frequency Ω, measuring the DC offset current I_{DC1}=I_{DC}(Ω=0) in the primary coil corresponding to B₁=B_{E},

bringing the core into a steady state of rotation at frequency Ωₘₐₓ, Ωₘₐₓ≠0,

measuring the rotation frequency Ωₘₐₓ,

measuring the balancing DC offset current I_{DC2} in the primary coil at the rotation frequency Ωₘₐₓ,

stopping the rotation of the core,

providing means for producing an adjustable, homogeneous magnetic field in the volume around the core,

producing a homogeneous magnetic field of a strength B₂ equal to the sum of the external magnetic field B_{E} and the gyromagnetic field B=Ωₘₐₓ, B₂=B_{E}+Ωₘₐₓ, producing said magnetic field to achieve the offset current I_{DC2} in the primary coil at the rotation frequency Ωₘₐₓ.

This first calibration step is then repeated a number of times, such that the method comprises,

adjusting a homogeneous magnetic field strength Bₙ₋₁,

rotating the core at a rotation frequency Ωₘₐₓ, which is measured,

measuring the DC offset current I_{DCn} in the primary coil at the rotation frequency Ωₘₐₓ,

stopping the rotation of the core,

producing a homogeneous magnetic field of a strength Bₙ equal to the sum of the external magnetic field B_{E} and the gyromagnetic field B=(n−1)Ωₘₐₓ, Bₙ=B_{E}+(n−1)Ωₘₐₓ producing said magnetic field to achieve offset current I_{DCn} in the primary coil at the rotation frequency Ωₘₐₓ.

Also for the extended calibration, an absolute zero point for the field measurement can be obtained by including

providing a volume without a magnetic field component in a first direction,

placing the fluxgate sensor in this volume with the core aligned parallel with this first direction,

measuring the DC offset current in the primary coil I_{DC0} in this volume for calibration of the magnetometer at zero magnetic field strength.

### SHORT DESCRIPTION OF THE DRAWINGS

The invention will be explained in more detail with reference to the drawing, where

FIG. 1 is a drawing of a fluxgate sensor with one core,

FIG. 2 shows diagrams of different values related to the functioning of fluxgates,

FIG. 3 shows diagrams of different values related to the functioning of fluxgates,

FIG. 4 is a drawing of a fluxgate sensor with two cores and primary windings,

FIG. 5 shows diagrams of different values related to the functioning of fluxgates,

FIG. 6 shows diagrams of different values related to the functioning of fluxgates,

FIG. 7 shows a setup for calibration,

FIG. 8 shows schematic calibration curves.

### DETAILED DESCRIPTION/PREFERRED EMBODIMENT

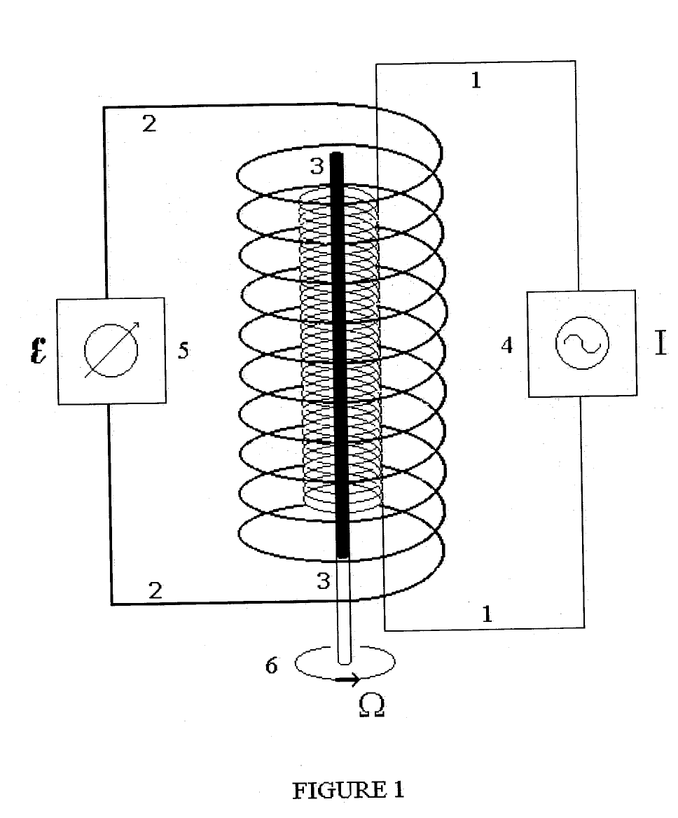

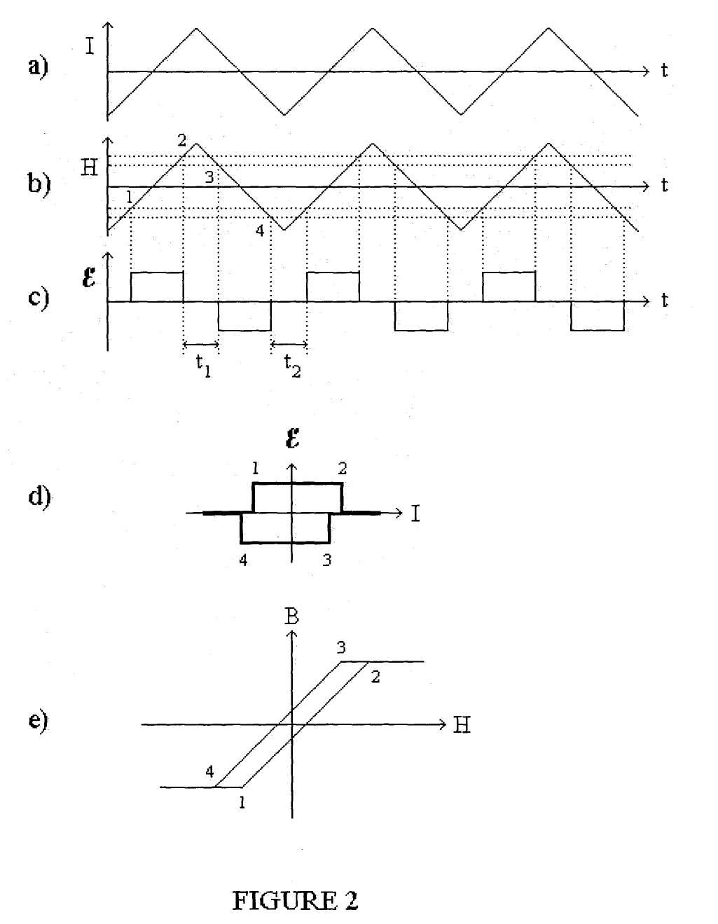

In FIG. 1, a fluxgate sensor is shown having a straight core 3, a primary coil I around the core 3 and a secondary coil 2 around the core 3. The primary coil is driven from a generator 4 by a varying current I(t), which may have different shapes, where one possibility is illustrated in FIG. 2a, for inducing magnetisation of the core 3 in the flux-gate sensor.

The magnetic properties of the core 3 influence the magnetic field B in the region within the secondary coil 2. Due to magnetic hysteresis of the core 3, the magnetic intensity H, see FIG. 2b, from the current in the primary coil 1 and the magnetic field B behave in principle as illustrated in FIG. 2e, where the ferromagnetic core is driven into magnetic saturation in each cycle.

The variation of the field B is measured by the induced electromotive force E in the secondary coil 2 functionally connected to detection means 5.

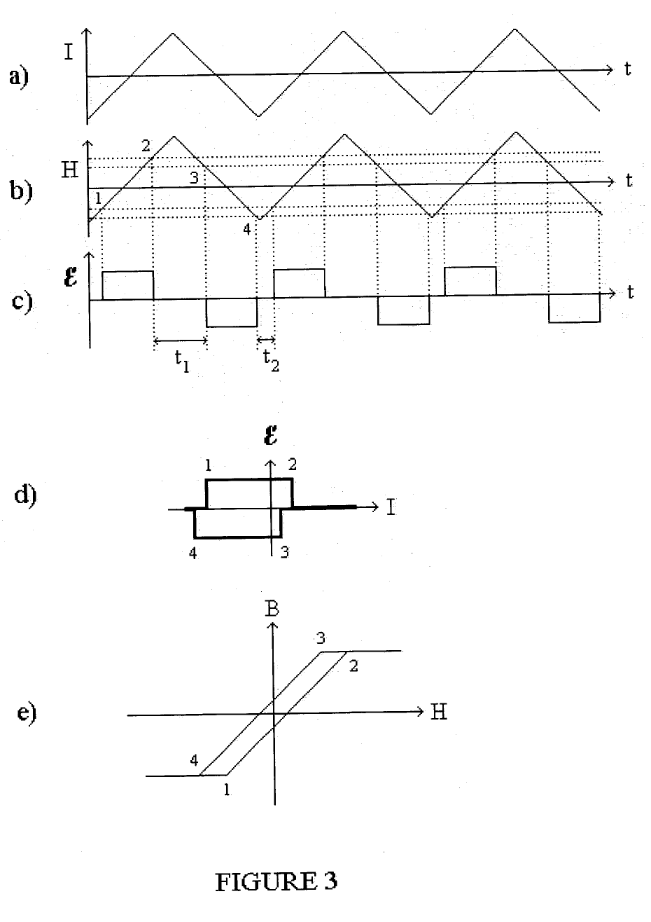

The induced electromotive force E is symmetric in time (FIG. 2c where t₁=t₂) or in the interval of currents (FIG. 2d) when the DC-offset of the current I is zero as in FIG. 2a and no external magnetic field is present. If an external magnetic field with a component parallel to the core appears then a constant value Hₚₐᵣ is added to H(t) and it becomes asymmetic about H=0 as in FIG. 3b. The electromotive force E consequently becomes asymmetric in time, as illustrated in FIG. 3c where t₁≠t₂, or in the interval of currents, as illustrated in FIG. 3d. The symmetry can be restored by adding a DC off-set current I_{DC} to I(t). This DC current is a measure of the strength of the external field in the direction of the core. In a fluxgate magnetometer according to the invention as well as magnetometers according to prior art, such a DC offset current is automatically adjusted in order to perform the measurement of the magnetic field.

The magnetometer according to the invention, as shown in FIG. 1, has means 6 for steadily rotating the core 3 around its longitudinal axis at the frequency Ω. The rotation is indicated by an arrow, which, however, does not limit the rotation into a specific direction.

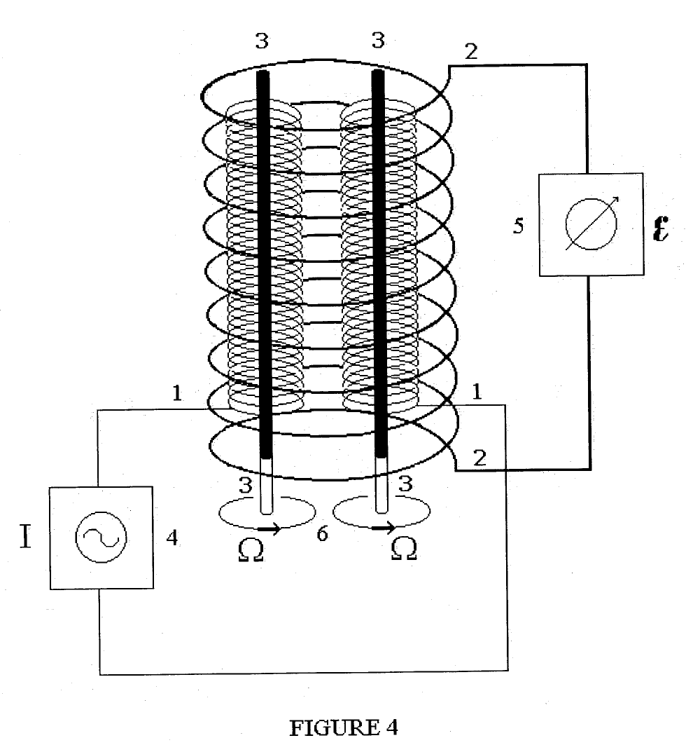

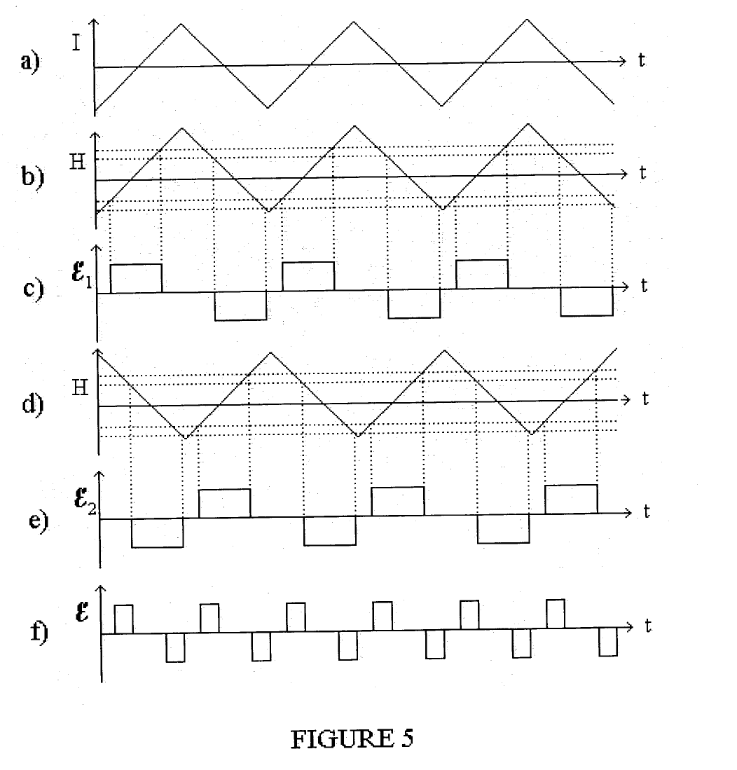

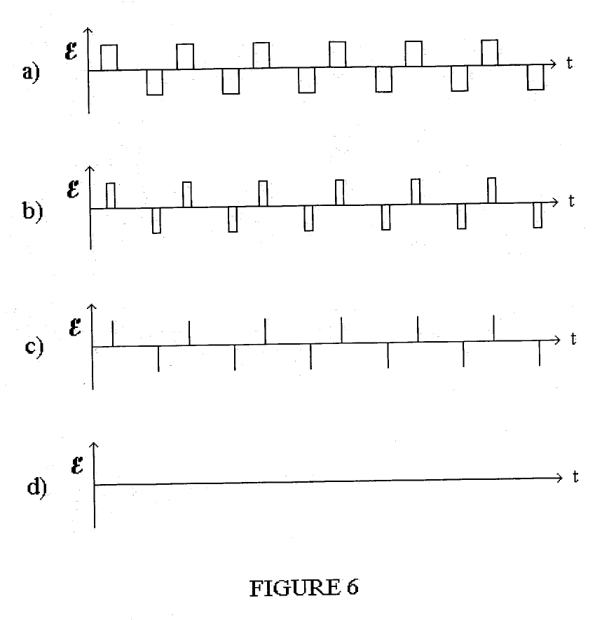

The fluxgate sensor according to the invention is not limited to one single ferromagnetic core, as illustrated in principle in FIG. 4. This sensor has two parallel cores 3, which may be rotated in the same directions and at the same frequency Ω, and two primary coils 1 with windings giving opposite field directions. The electromotive force E induced in the secondary coil 2 is shown in FIG. 5 for a certain unbalance of H. It has two components E₁ and E₂, one from each core. The two components have opposite signs, so they tend to compensate each other. The compensation is complete when the sensor is in balance. This is illustrated in FIG. 6. The unbalance is largest in FIG. 6a. In FIGS. 6b and 6c it gradually becomes smaller, and in FIG. 6d the sensor is balanced.

In the shown embodiment FIG. 1, the secondary coil 2 is placed around the primary coil 1. However, the secondary coil may be arranged around a certain part of the core while the primary coil is arranged around a different part of the core. As a further alternative, an arrangement may be envisaged with multiple coils.

In the following, a local calibration technique and a calibration technique for a large interval, full calibration, will be explained.

### Local (or Differential) Calibration—Small Variations in B

The fluxgate magnetometer may be calibrated for absolute values of small variations in B by bringing the core material into a state of steady rotation. Measurements of the rotation frequency Ω and the DC-offset current in the primary coil I_{DC}(Ω) during rotation, and of I_{DC(}0) for the core material at rest determine the quantity

ΔB/ΔI_{DC}=(B(Ω)−B(0))/(I_{DC}(Ω)−I_{DC}(0))=(B(0)+Ω−B(0))/(I_{DC}(Ω)−I_{DC}(0))=Ω/(I_{DC}(Ω)−I_{DC(0)),}

which may subsequently be used to obtain absolute values of naturally occurring or artificial variations of B, ΔB(t).

It should be borne in mind that ΔB=Ω in atomic units, which were chosen to simplify the expressions. In SI units, ΔB[nT]=35.6825 f [kHz] with 2πf=Ω.

The slope ΔB/ΔI_{DC} may depend (weakly) on B, so the calibration is merely a local one. The largest possible local calibration range is determined by the maximum rotation frequency Ωₘₐₓ, i.e. B(0)±Ωₘₐₓ, where B(0) is the magnetic field for the core at rest.

The local calibration can be performed continually, while the magnetometer is being used, by periodically varying the rotation frequency, for example harmonically as Ω=Ωₘₐₓ cos(Ω+φ) at a suitable and precisely known frequency Ω. The imposed time-dependence is subsequently filtered out of the measured time-dependence of B and used for the continuing calibration.

The local calibration supplemented by a determination of the fluxgate reading for the vanishingly small field-strength inside a μ-metal shielded region would constitute a full calibration, if ΔB/ΔI_{DC} were a constant independent of B.

### Full Calibration

A full calibration of the fluxgate sensor can be accomplished by following a procedure similar to the one listed below. Such a procedure can be programmed and run by a microcontroller.

The fluxgate sensor with the core at rest is first placed in a L-metal shielded region for achieving zero reading of the sensor, I_{DC0}=I_{DC}(B=0).

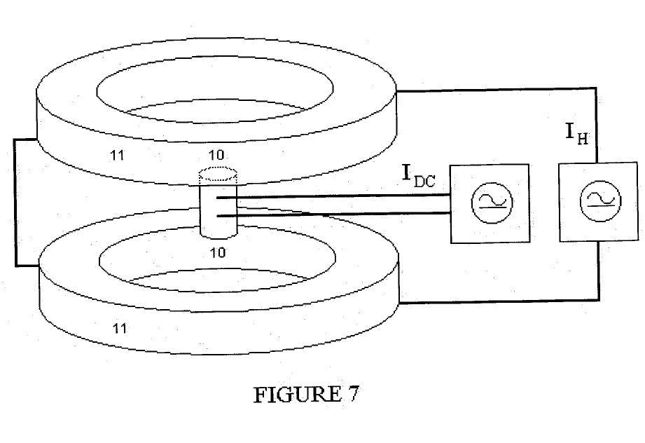

The fluxgate sensor 10 is then placed near the middle of a Helmholtz pair 11, as illustrated in FIG. 7, and orientated such that the core is aligned, at least approximately, with the homogeneous field from the pair of coils. The current in the Helmholtz coils is I_{H}=I_{H1}=0 and Ω=0 at this stage. An external field of strength B_{E} in the direction of the sensor core may be present (f.ex. a component of Earth's magnetic field).

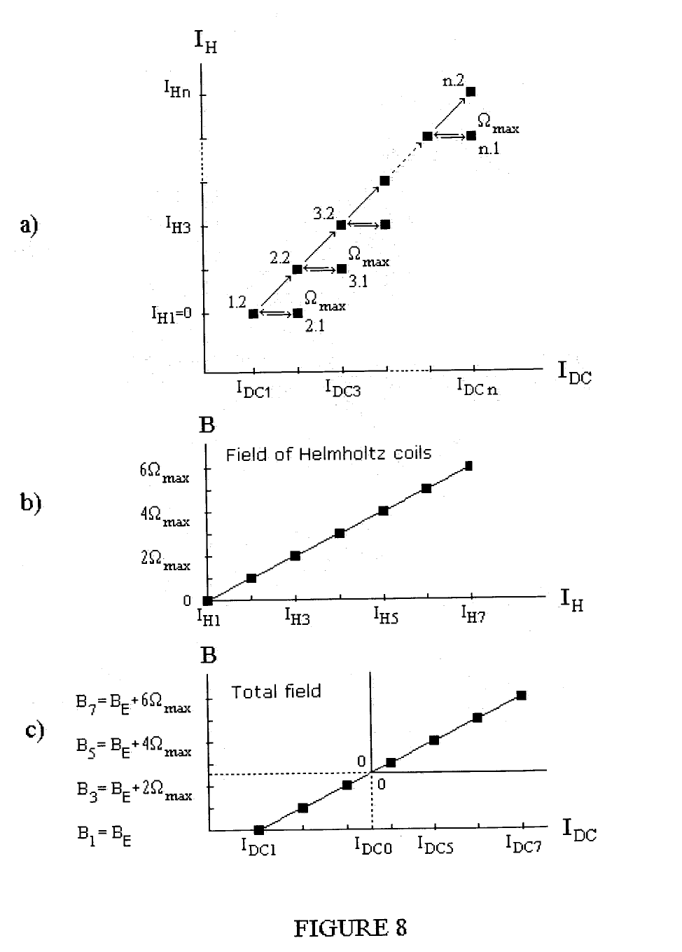

Following this, the next steps of the calibration procedure is to keep the current turned off in the Helmholtz pair, I_{H1}=0, log the fluxgate reading, I_{DC1}, for the external field B₁=B_{E} (with reference to FIG. 8, this situation corresponds to point 1.2 in the drawing, where I_{H}=I_{H1}=0 and Ω=0), rotate the core at the frequency Ωₘₐₓ (2.1 in FIG. 8), and log the fluxgate reading I_{DC2}=I_{DC}(Ωₘₐₓ) Then, the rotation of the core is stopped (1.2 in FIG. 8), and I_{H} is adjusted in order to obtain the same fluxgate reading I_{DC2} as during rotation, which happens at I_{H2}=I_{H}(Ωₘₐₓ) (2.2 in FIG. 8) when the field produced by the Helmholtz pair is exactly Ω, and the total field in the Helmholtz pair is exactly B₂=B_{E}+Ωₘₐₓ.

In the next steps of the calibration, the field B₂ is left unchanged (I_{H}=I_{H2}), the core is again rotated at the frequency Ωₘₐₓ, the fluxgate reading I_{DC3}=I_{DC}(2Ωₘₐₓ) is logged. This corresponds to point 3.1 in FIG. 8. Then, the core is stopped, I_{H} is adjusted for the same fluxgate reading I_{DC3}, which happens at I_{H3}=I_{H}(2Ωₘₐₓ) when the field produced by the Helmholtz pair is exactly 2Ωₘₐₓ and the total field in the Helmholtz pair is exactly B₃=B_{E}+2Ωₘₐₓ, corresponding to point 3.2.

This procedure is repeated, resulting in calibration curves as illustrated in FIG. 8.

After the completion of n calibration steps, two sets of currents [I_{DC1},I_{DC2}, . . . ,I_{DCn}] and [I_{H1}, I_{H2}, . . . ,I_{Hn}] are obtained, which correspond to a set of known field values produced by the Helmholtz coils [0,Ωₘₐₓ, 2Ω_{max, . . . ,(n-}1)Ωₘₐₓ]=[B₁−B_{E},B₂−B_{E}, . . . ,Bₙ−B_{E}]. This constitutes a calibration of the Helmholtz pair in terms of the calibration points [(0,0), (I_{H2},Ωₘₐₓ), . . . ,(I_{Hn},(n−1)Ωₘₐₓ)] as illustrated in FIG. 8b, and when combined with the zero-field measurement it determines B_{E} and the calibration of the fluxgate sensor in terms of the calibration points [(I_{DC0},0),(I_{DC1},B_{E}),(I_{DC2},B_{E}+Ωₘₐₓ), . . . ,(I_{DCn},B_{E}+(n−1) Ωₘₐₓ) illustrated in FIG. 8c.

A full calibration of the fluxgate sensor implies the determination of the zero point on the B-scale (FIG.8c). When a full calibration procedure requires many steps one must consider the possibility of an accumulation of errors. Such considerations are relevant also if the field of the Helmholtz coils is to be calibrated over a broad range. On the assumption that Ωₘₐₓ can be determined essentially without error so that the calibration uncertainty in each step is due only to statistical fluctuations in the reading I_{DC(Ω}ₘₐₓ), an accumulated error of

Δ=[Σₖ(ΔI_{DCk})²]^{1/2}≅[n]^{1/2} ΔI_{DC}

must be expected, where Σₖ means summation over calibration steps k, n is the number of steps, ΔI_{DCk} is the statistical reading error of the k-th step, and ΔI_{DC} is the averaged reading error, which is close to ΔI_{DCk}, because the dependence on k is weak.

When the calibration is repeated N times the error is improved according to

Δ_{N}=Δ/[N]^{1/2}.

In practice, the invention can be realized as follows in a rather simple way. The straight and static ferromagnetic core in prior art fluxgates may be replaced by a similar core that can be brought into steady, high speed rotation. Very high mechanical rotation frequencies are possible and used routinely, for instance, in dental drills. A realistic value of f=Ω/2π is 450,000 rpm or 7.50 kHz, which corresponds to a field-strength of 268 nT equal to 2.68.10⁻³ Gauss. Such rotational frequencies are feasible, for example with reference to US Pat. No. 5,334,013. It should be noted, that the system works like a conventional sensor, when the core is at rest.

In order to perform the calibration routine as described above, a μ-metal box and a solenoid, a Helmholtz coil pair or another means of producing a homogeneous B-field, are needed. It is understood that the secondary windings of the fluxgate sensor may be used for the purpose of an external solenoid.

Rotation frequencies f of almost 10 kHz have been realized for small objects (see patent EP 0 249 383 A2). For fₘₐₓ=7.5 kHz, which corresponds to 268 nT, a full calibration of the range 0-1 Gauss (0-100,000 nT) involves 100,000/268=373 measuring points, which is easily achievable by using a microcontroller repeating the calibration cycles automatically after suitable programming.

1. A magnetometer for measuring a magnetic field, comprising a fluxgate sensor with
at least one ferromagnetic core,
a primary, electrically conducting coil arranged around the core for periodical magnetisation of the core into magnetic saturation by an alternating electric current through the primary coil, and
a secondary, electrically conducting coil arranged around the at least one ferromagnetic core for producing a measurable electromotive force as a response signal,
wherein the magnetometer has means for rotating the at least one core of the fluxgate sensor with a steady rotation inside the coils during the measurement of the magnetic field.

2. A magnetometer according to claim 1, wherein the magnetometer has means for measuring the electromotive force produced in the secondary coil.

3. A magnetometer according to claim 2, wherein the magnetometer has means for supplying an alternating electric current through the primary coil.

4. A magnetometer according to claim 1, wherein the fluxgate sensor has two cores, each core being surrounded by a primary coil, both cores being surrounded by one secondary coil, the two cores being configured to be rotated in the same direction by rotation means.

5. Method for calibration of a magnetometer, the magnetometer having a fluxgate sensor with
at least one ferromagnetic core,
a primary, electrically conducting coil arranged around the core for periodical magnetisation of the core into magnetic saturation by an alternating electric current through the primary coil, and
a secondary, electrically conducting coil arranged around the at least one ferromagnetic core for producing a measurable electromotive force as a response signal wherein the magnetometer has means for rotating the at least one core of the fluxgate sensor with a steady rotation inside the coils during selected measurements of the magnetic field,
the fluxgate sensor being configured to provide and adjust a DC offset current I_{DC} in the primary coil, the value of the DC offset current in the primary coil being adjusted to create a magnetic field balancing the magnetic field B experienced by the secondary coil, the method comprising,
for an external magnetic field B_{E} in the direction parallel with the core, without rotation of the core at rotation frequency Ω, measuring the DC offset current I_{DC}(Ω=0) in the primary coil,
bringing the core into a steady state of rotation at frequency Ω, Ω≠0,
measuring the rotation frequency Ω,
measuring the balancing DC offset current I_{DC}(Ω) at the rotation frequency Ω,
using the gyromagnetic effect for determination of the gradient ΔB/ΔI_{DC} of the external magnetic field variation ΔB relative to the variation in the offset current ΔI_{DC} necessary to balance this variation, this determination implying calculating the ratio Ω/(I_{DC}(Ω)-I_{DC}(0)) between the rotation frequency Ω and the difference between the offset current I_{DC}(Ω) at frequency Ω and the offset current I_{DC}(0) without rotation of the core.

6. The method according to claim 5, wherein the method comprises
providing a volume without a magnetic field component in a first direction,
placing the fluxgate sensor in this volume with the core aligned parallel with this first direction,
measuring the DC offset current in the primary coil 1_{DC0} in this volume for calibration of the magnetometer at zero magnetic field strength.

7. Method for calibration of a magnetometer, the magnetometer having a fluxgate sensor with
at least one ferromagnetic core,
a primary, electrically conducting coil arranged around the core for periodical magnetisation of the core into magnetic saturation by an alternating electric current through the primary coil, and
a secondary, electrically conducting coil arranged around the at least one ferromagnetic core for producing a measurable electromotive force as a response signal wherein the magnetometer has means for rotating the at least one core of the fluxgate sensor with a steady rotation inside the coils during the measurement of the magnetic field,
the fluxgate sensor being configured to provide and adjust a DC offset current I_{DC} in the primary coil, the value of the DC offset current in the primary coil being adjusted to create a magnetic field balancing the magnetic field B experienced by the secondary coil, the method comprising,
for an external magnetic field B_{E}, without rotation of the core at rotation frequency Ω, measuring the DC offset current I_{DC}(Ω=0) in the primary coil,
bringing the core into a steady state of rotation at frequency Ωₘₐₓ, Ωₘₐₓ≠0,
measuring the rotation frequency Ωₘₐₓ,
measuring the balancing DC offset current I_{DC}(Ωₘₐₓ) in the primary coil at the rotation frequency Ωₘₐₓ,
stopping the rotation of the core,
providing means for producing an adjustable, homogeneous magnetic field in the volume around the core,
producing a homogeneous magnetic field of a strength B₂ equal to the sum of the external magnetic field B_{E} and the gyromagnetic field B=Ωₘₐₓ, B₂=B_{E}+Ωₘₐₓ, producing said magnetic field to achieve offset current I_{DC}(Ωₘₐₓ) in the primary coil at the rotation frequency Ωₘₐₓ.

8. Method for calibration according to claim 7, wherein the method comprises a repeated procedure, wherein the method comprises
adjusting a homogeneous magnetic field strength Bₙ₋₁,
rotating the core at a rotation frequency Ωₘₐₓ, which is measured,
measuring the DC offset current I_{DC}(Ωₘₐₓ) in the primary coil at the rotation frequency Ωₘₐₓ,
stopping the rotation of the core,
producing a homogeneous magnetic field of a strength Bₙ, equal to the sum of the external magnetic field B_{E} and the gyromagnetic field B=(n−1)Ωₘₐₓ, Bₙ=B_{E}+(n−1)Ωₘₐₓ producing said magnetic field to achieve offset current I_{DC}(Ωₘₐₓ) in the primary coil at the rotation frequency (n−1)Ωₘₐₓ.

9. The method according to claim 7, wherein the method comprises
providing a volume without a magnetic field component in a first direction,
placing the fluxgate sensor in this volume with the core aligned parallel with this first direction,
measuring the DC offset current in the primary coil I_{DC0} in this volume for calibration of the magnetometer at zero magnetic field strength.
